(19) United States
(12) Patent Application Publication
(10) Pub. No.: US 2012/0126678 A1
(43) Pub. Date: May 24, 2012

(54) Apparatus for Retaining an Object

(75) Inventor: Marko EROMAKI, Tampere (FI)

(73) Assignee: Nokia Corporation

(21) Appl. No.: 12/951,475

(22) Filed: Nov. 22, 2010

(51) Int. Cl. H05K 7/14; F16M 13/02; A47B 95/00; H05K 3/00; F16M 13/00

(52) U.S. Cl. 312/350; 29/829; 248/309.1; 248/220.21

(57) ABSTRACT

An apparatus including:
a first support and a second support separated by a distance;
a stiff member configured to extend lengthwise between the first support and the second support and having a length greater than the distance; and
one or more retaining members coupled to the stiff member
wherein the stiff member has a first configuration in which the stiff member has an outward curvature and the one or more retaining member are in a non-retaining configuration and
wherein the stiff member has a second configuration in which the stiff member has an inward curvature and the one or more retaining members are in a retaining configuration.

### TECHNOLOGICAL FIELD

Embodiments of the present invention relate to an apparatus for retaining an object. In particular, some embodiments relate to an apparatus for retaining a component in an electronic device.

### BACKGROUND

Currently, an object such as a component for an electronic device is interconnected to a printing wiring board of the device either directly or via a socket. Direct interconnection of a component results in it being difficult to exchange the component should it develop a fault. Although the use of a releasable socket addresses this problem, it typically adds depth to the device which may be problematic when the component is deep and the device is a thin device such as a hand-portable electronic device.

### BRIEF SUMMARY

According to various, but not necessarily all, embodiments of the invention there is provided an apparatus comprising: a first support and a second support separated by a distance; a stiff member configured to extend lengthwise between the first support and the second support and having a length greater than the distance; and one or more retaining members coupled to the stiff member wherein the stiff member has a first configuration in which the stiff member has an outward curvature and the one or more retaining member are in a non-retaining configuration and wherein the stiff member has a second configuration in which the stiff member has an inward curvature and the one or more retaining members are in a retaining configuration.

According to various, but not necessarily all, embodiments of the invention there is provided a method comprising: inwardly inserting a component against an outwardly curved stiff member that spans a distance less than its length; continuing to inwardly insert the component against the outwardly curved stiff member until the stiff member buckles to become inwardly curved causing one or more retaining members coupled to the stiff member to retain the component.

According to various, but not necessarily all, embodiments of the invention there is provided a method comprising: applying an outward force against an inwardly curved stiff member that spans a distance less than its length and that uses one or more retaining members to retain a component; and continuing to apply an outward force until the stiff member buckles to become outwardly curved causing the one or more retaining members to release the component.

Some or all embodiments of the invention may have certain advantages such as:

The apparatus, when the stiff member is in the second configuration, may retain an object at or very close to an underlying supporting surface such as a printed wiring board. The apparatus therefore does not significantly increase the depth of a device housing the apparatus beyond that required by the depth of the retained component itself.

The apparatus may operate within well defined depth tolerances meaning that the device does not have to have a significantly increased depth to accommodate variations in the position of the retained component.

The stiff member of the apparatus, when in the second configuration, may ensure good electrical contact between a retained object and underlying electrical contacts by forcing the retained object towards the underlying electrical contacts.

The apparatus may operate to simply release a retained component.

### BRIEF DESCRIPTION

For a better understanding of various examples of embodiments of the present invention reference will now be made by way of example only to the accompanying drawings in which:

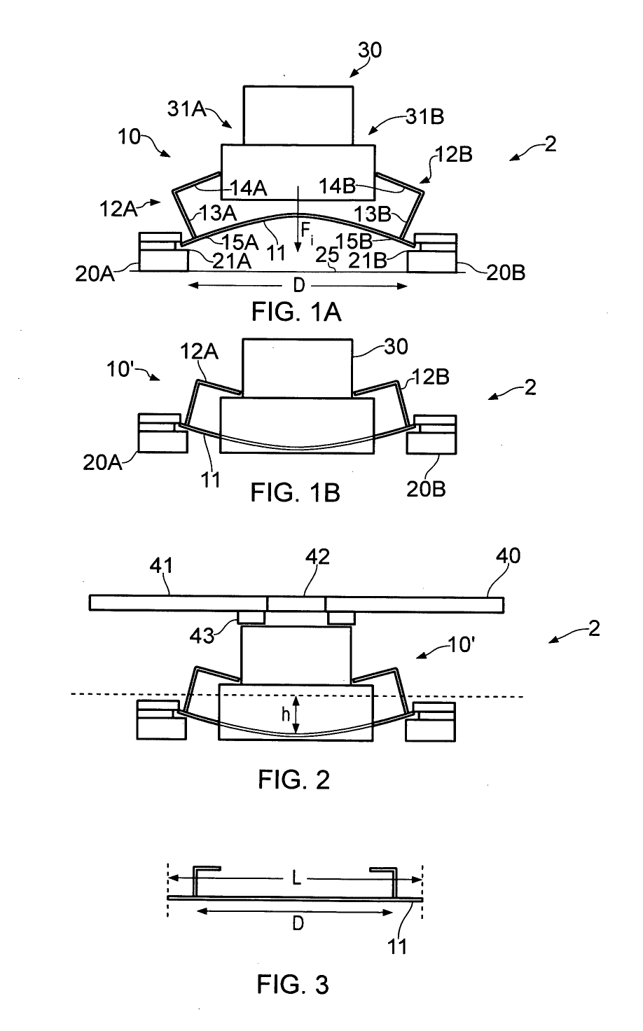

FIGS. 1A and 1B illustrate a method for retaining an object in an apparatus;

FIG. 1A illustrates an example of an apparatus where a stiff member has a first configuration in which the stiff member has an outward curvature and one or more retaining members are in a non-retaining configuration;

FIG. 1B illustrates an example of an apparatus where a stiff member has a second configuration in which the stiff member has an inward curvature and one or more retaining members are in a retaining configuration;

FIG. 2 illustrates an example of an apparatus where a stiff member has a second configuration in which the stiff member has an inward curvature and one or more retaining members are in a retaining configuration and a retainer is used to constrain outward movement of the stiff member;

FIG. 3 illustrates an example of a stiff member when flat;

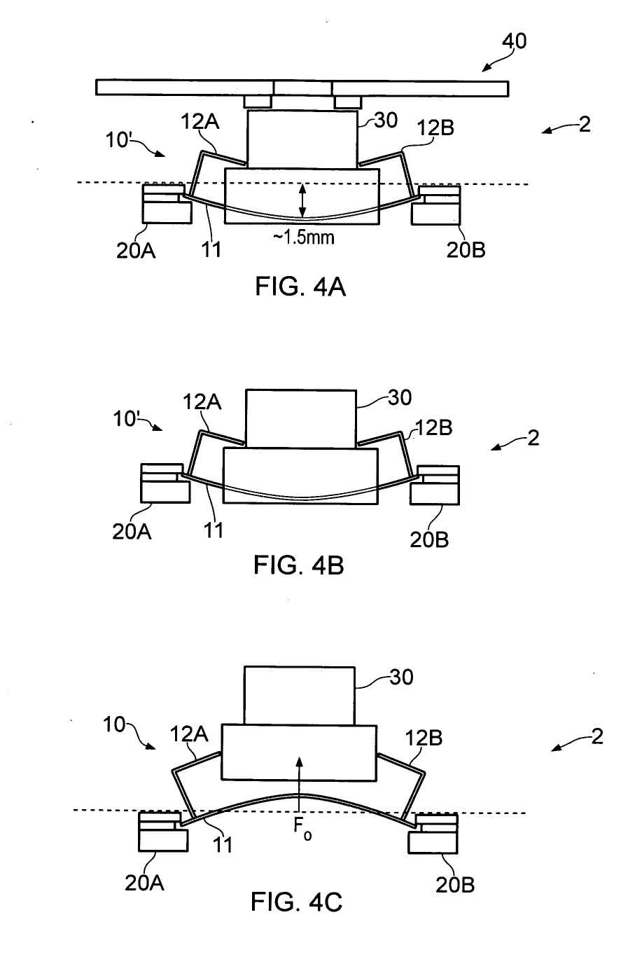

FIGS. 4A, 4B and 4C illustrate a method comprising of removing a retained object from the apparatus;

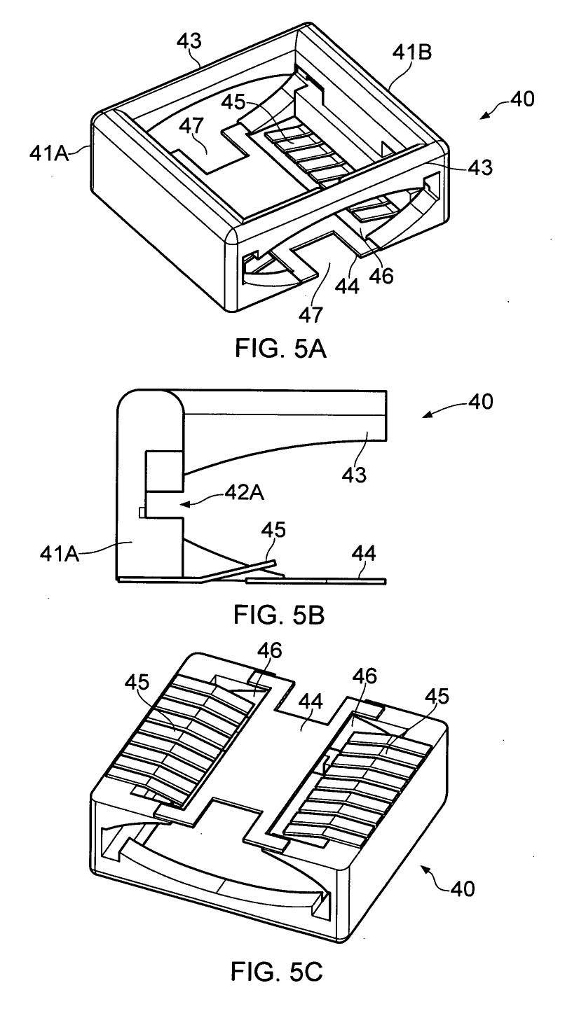

FIGS. 5A, 5B and 5C illustrate an example of a housing for the stiff member from a top perspective view, a side view and a rear perspective view;

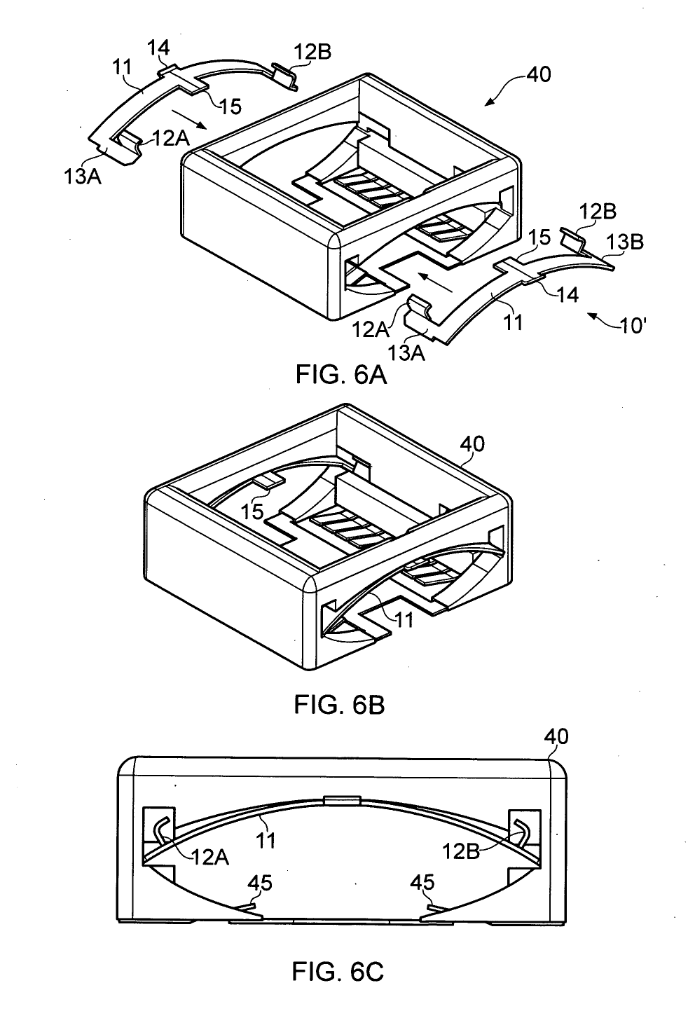

FIGS. 6A, 6B and 6C illustrate the relationship between a stiff member and the housing from a top perspective view during insertion, from a top perspective view after insertion and from a side view after insertion;

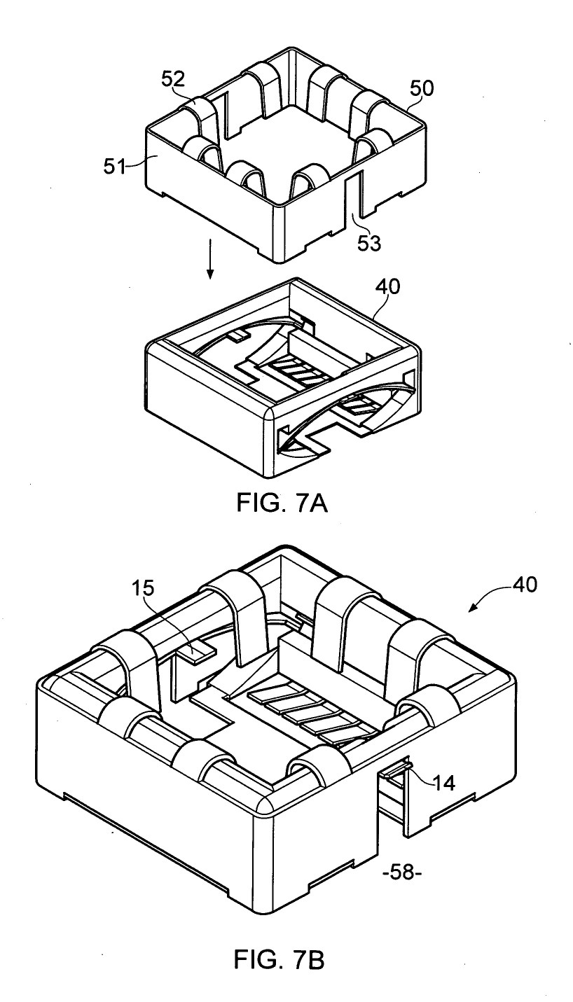

FIGS. 7A and 7B illustrate the addition of electro-magnetic shielding to the housing;

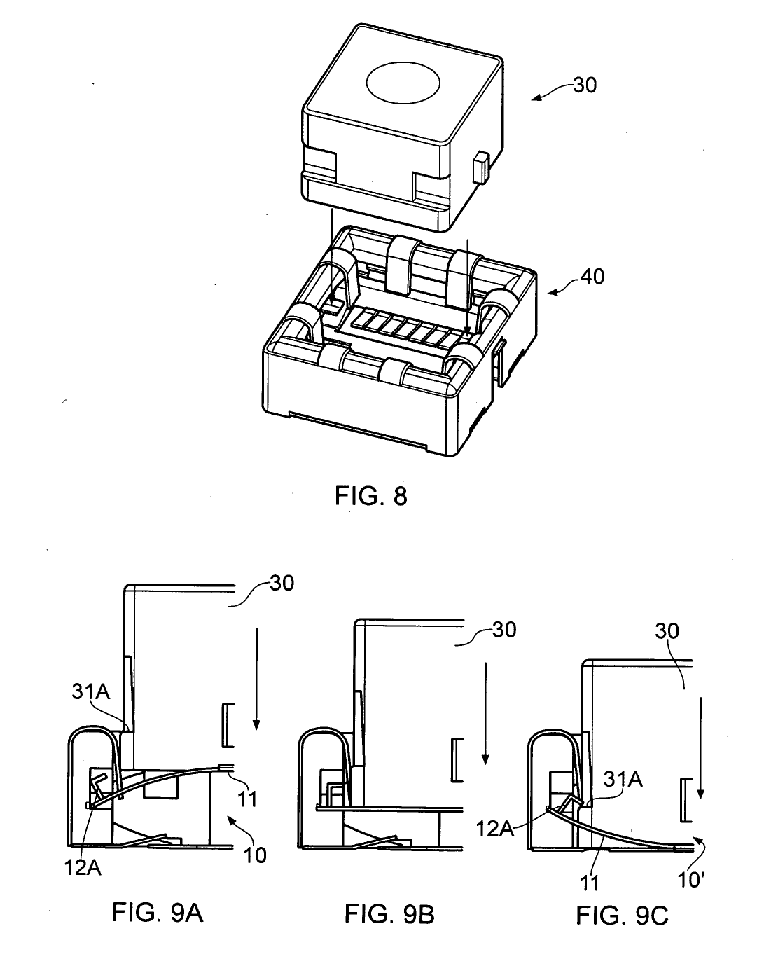

FIG. 8 is a top perspective view during insertion of an object into the housing for retention;

FIGS. 9A, 9B, 9C are side views of the housing during insertion of an object into the housing for retention;

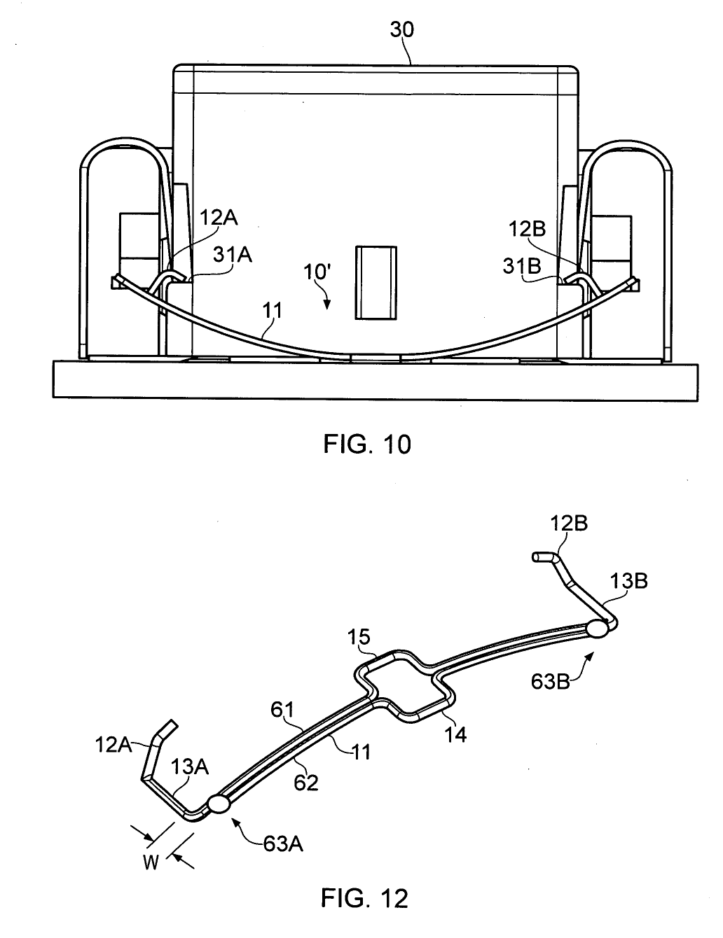

FIG. 10 is a side view of the housing after insertion of an object into the housing and retention of the object;

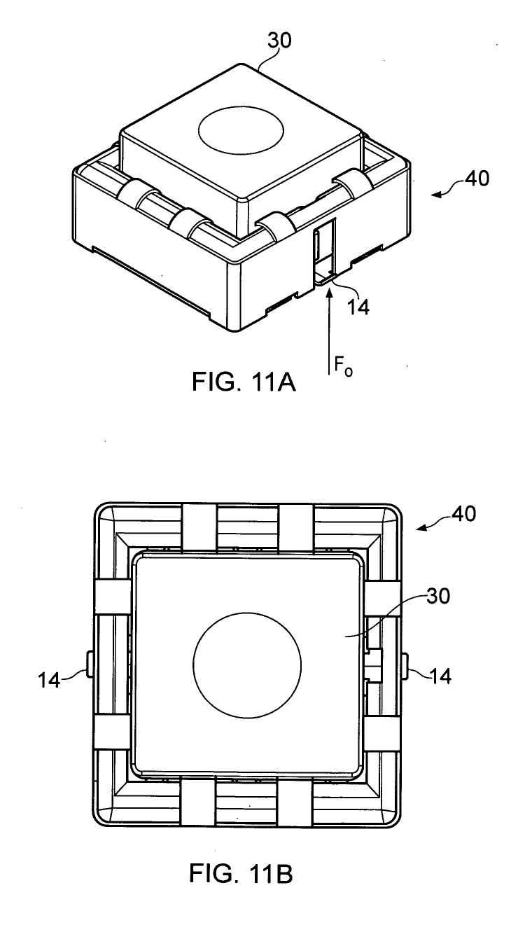

FIGS. 11A and 11B illustrate release of a retained object from the housing from a top perspective view and from a plan view; and

FIG. 12 illustrates an example of an alternative stiff member.

### DETAILED DESCRIPTION

The Figures illustrate examples of an apparatus 2 comprising: a first support 20A and a second support 20B separated by a distance D; a stiff member 11 configured to extend lengthwise between the first support 20A and the second support 20B and having a length L greater than the distance D; and one or more retaining members 12A, 12B coupled to the stiff member 11, wherein the stiff member 11 has a first configuration 10 in which the stiff member 11 has an outward curvature and the one or more retaining members 12A, 12B are in a non-retaining configuration and wherein the stiff member 11 has a second configuration 10′ in which the stiff member 11 has an inward curvature and the one or more retaining members 12A, 12B are in a retaining configuration.

FIGS. 1A and 1B illustrate an example of an apparatus 2 comprising a first support 20A and a second support 20B separated by a distance D. A stiff member 11 is configured to extend lengthwise between the first support 20A and the second support 20B.

As illustrated in FIG. 3, the stiff member 11 has a length L greater than the distance D.

In FIG. 1A, the stiff member 11 has a first configuration 10 in which the stiff member 11 has an outward curvature.

In FIG. 1B, the stiff member 11 has a second configuration 10′ in which the stiff member 11 has an inward curvature.

In the first and second configurations, the stiff member 11 is arcuate having a bow shape that curves only in a single sense. However, the sense of curvature in the first configuration (convex) is the opposite of the sense of curvature in the second configuration (concave). In the first configuration, a tangent to the arcuate curve rotates in only one direction as one progresses along the curve, however, the sense of rotation is different in the first and second configurations.

A first retaining member 12A extends from an outward surface of the stiff member 11 at a first position 15A. The first position 15A is towards an extremity of the stiff member 11 that is supported by the first support 20A.

A second retaining member 12B extends from the outward surface of the stiff member 11 at a second position 15B. The second position 15B is towards an extremity of the stiff member 11 that is supported by the second support 20B.

When the stiff member 11 is in the first configuration 10, in which the stiff member 11 has an outward curvature, the opposing retaining members 12A, 12B are in a non-retaining configuration.

When the stiff member 11 is in the second configuration 10′, in which the stiff member 11 has an inward curvature, the opposing retaining members 12A, 12B are in a retaining configuration. In the retaining configuration, the retaining members 12A, 12B applies a continuous inward retaining force against a retained object 30.

The retained object 30 is sized and configured for retention by the retaining members 12A, 12B. In the illustrated example, the object 30 has a first protruding portion 31A, formed by a step or shoulder in a side of the object 30, that is contacted by the first retaining member 12A and has a second protruding portion 31B, formed by a step or shoulder in an opposing side of the object 30, that is contacted by the second retaining member 12B.

The object 30 may be a module for use in a hand-portable electronic device such as a mobile cellular telephone or a personal media device or personal gaming device. The object 30 may be a digital camera module that includes optics.

Each retaining member 12A, 12B, in this example, comprises an outwardly extending supporting portion 13A, 13B that supports a contact portion 14A, 14B for contacting the object 30 retained by the retaining members 12A, 12B.

In one specific example illustrated, the supporting portions 13A, 13B extend outwardly substantially perpendicular to the stiff member 11 and the contact portion 14A, 14B extend from the supporting portions towards each other substantially perpendicular to the supporting portions 13A, 13B.

When the stiff member 11 changes shape from an outward curvature in the first configuration 10 to an inward curvature in the second configuration 10′, the first contact portion 14A and the second contact portion 14B are moved inwardly and towards each other. The first contact portion 14A is rotated in a first sense (clockwise in FIGS. 1A and 1B) about the first position 15A and the second contact portion 14B is rotated in a second sense (anticlockwise in FIGS. 1A and 1B), opposite to the first sense, about the second position 15B. The contact portions 14A, 14B are brought into contact with the object 30 and because of the stiffness of the supporting portions 13A, 13B and contact portions 14A, 14B retain the object 30.

The movement of the contact portions 14A, 14B may result in the object 30 being pinched between the opposing pair of contact portions 14A, 14B and/or the object 30 being pushed by the pair of contact portions 14A, 14B against an underlying supporting surface 25.

The underlying supporting surface may comprise a site area 25 between the first support 20A and the second support 20B.

In the illustrated example, the stiff member 11 has a first extremity supported by the first support 20A, a second extremity supported by the second support 20B and an intermediate portion, between the first and second extremities that is brought from a significant distance above the site area 25, in the first configuration 10, to contact with the site area 25 in the second configuration 10′.

The site area may comprise one or more electrical contacts for contacting an inserted object 30.

In the illustrated example of FIGS. 1A and 1B, the first support 20A provides a first support surface 21A on which the first extremity of the stiff member 11 rests and the second support 20B provides a second support surface 21B on which the second extremity of stiff member 11 rests.

In this example, the first support 20A provides for at least some freedom of movement of the stiff member 11 such that in the first and second configurations different parts of the first extremity of the rigid member 11 may contact the first support surface 21A. The first extremity has enough freedom of movement to ‘flip’ when the configuration changes. Likewise, the second support 20B provides for at least some freedom of movement of the stiff member 11 such that in the first and second configurations different parts of the second extremity of the rigid member 11 may contact the first support surface 21A. The first extremity has enough freedom of movement to ‘flip’ when the configuration changes.

In FIG. 2, a retainer 40 is used to constrain outward movement of the stiff member 11 when it is in the second configuration 10′. In this example, the retainer 20 is formed by a cover 41 that overlies the retained object. The cover 41 may be an external cover of a hand-portable electronic device that is applied during manufacture of the device. The cover is separated from the object 30, in this example, by a resiliently flexible gasket 43. If the object 30 is a camera module, an aperture 42 in the cover 41, and an aperture in the gasket 43 may be aligned with an aperture of the camera module.

The apparatus 2 may be a bi-stable apparatus, having a first stable equilibrium configuration in which the stiff member 11 is in the first configuration 10 and a second stable equilibrium configuration in which the stiff member 11 is in the second configuration 10′. In the example of FIG. 2, the retainer 40 prevents the inadvertent transition from the first stable equilibrium configuration to the second stable equilibrium configuration which could occur if a sudden impulse caused the stiff member 11 to rise above the transition height h at which the stiff member 11 automatically flips from the second configuration 10′ to the first configuration 10.

FIGS. 1A and 1B together illustrate a method comprising: inwardly inserting a object or component 30 against an outwardly curved stiff member 11 that spans a distance D less than its length L; and continuing to inwardly insert the object 30 against the outwardly curved stiff member 11 until the stiff member 11 buckles to become inwardly curved causing one or more retaining members 12A, 12B coupled to the stiff member 11 to retain the object 30.

Thus, in response to an inwardly directed force of increasing magnitude provided via the object 30, the stiff member 11, while in the first configuration 10, initially provides resistance against the inwardly directed force and then buckles switching configuration from the first configuration 10 to the second configuration 10′.

This method may be used as part of a manufacturing process for a hand-portable electronic device.

FIGS. 4A, 4B and 4C illustrate a method comprising: removing the retainer 40 (if present) to enable outward movement of the inwardly curved stiff member 11; applying an outward force against an inwardly curved stiff member 11 that spans a distance D less than its length L and that uses one or more retaining members 12A, 12B to retain an object 30; and continuing to apply an outward force until the stiff member 11 buckles to become outwardly curved causing the one or more retaining members 12A, 12B to release the object 30.

Thus, in response to an outwardly directed force of increasing magnitude, the stiff member 11, while in the second configuration 10′, initially provides resistance against the outwardly directed force and then switches configuration from the second configuration 10′ to the first configuration 10.

The released object 30 can then be removed. A repair could be effected by inserting a new, replacement object 30 by inwardly inserting the replacement object against the outwardly curved stiff member 11 and continuing to inwardly insert the replacement object 30 against the outwardly curved stiff member 11 until the stiff member buckles to become inwardly curved causing one or more retaining members 12A, 12B coupled to the stiff member 11 to retain the replacement component.

The retainer 40 (if required) may then be put back in place to prevent outward movement of the inwardly curved stiff member 11.

FIGS. 5A, 5B and 5C illustrate an example of a housing 40 for the stiff member 11. FIG. 5A is a top perspective view, FIG. 5B is a side view and FIG. 5C is a rear perspective view.

The housing 40 may be formed from plastic. The illustrated example, has first and second opposing sidewalls 41A, 41B that are fixedly held in position by upper braces 43 that extend between the upper corners of the sidewalls 41A, 41B and a lower base 44 that extends between the lower edges of the sidewalls 41A, 41B.

A first notch 42A in an interior face of the first sidewall 41A at a rightmost edge of the first sidewall 41A provides the first support 20A for a first stiff member 11. A second notch 42B in an interior face of the second sidewall 41B at a rightmost edge of the first sidewall 41A provides the second support 20B for the first stiff member 11.

The first notch is open at the rightmost edge of the first sidewall 41A and the second notch is open at the rightmost edge of the second sidewall 41B. As shown in FIG. 6A, the stiff member 11 may be laterally inserted, from the right into the notches 41A, 41B such that it is supported between the first notch 41A and the second notch 42A in the first configuration 10.

Similar opposing notches may be present in the interior face of the first sidewall 41A at a leftmost edge of the first sidewall 41A and the interior face of the second sidewall 41B at a leftmost edge of the second sidewall 41B, and

another stiff member 11 may be laterally inserted, from the left into the notches such that they support the stiff member 11 in the first configuration 10.

The housing 40 additionally comprises insert molded contact springs 45 that extend outwardly from the bottom edge of the sidewalls into respective apertures 46 between the base 44 and respective sidewalls before rising outwardly from bends to form resiliently depressible spring lever contacts 45.

The base 44 is configured such that it can be used to pick-up and place the housing 40 by a robot during an automated manufacturing process. The base 44 may be made from sheet metal.

There are also notches 47 in the base 44 to the left and right to enable the stiff members 11 to contact an underlying supporting surface 25 when they are in the second configuration 10′ in which the stiff member 11 has an inward curvature and the retaining members 12A, 12B are in a retaining configuration.

FIGS. 6A, 6B and 6C illustrate the insertion of a stiff member 11 into the housing 40. FIG. 6A is a top perspective view during insertion. FIG. 6B is a top perspective view after insertion. FIG. 6C is a side view after insertion.

The stiff member 11 is elongate having a length that is significantly greater than its width and a width that is significantly greater than its thickness.

The stiff member comprises first retaining members 12A and second retaining members as described with reference to FIGS. 1A and 1B.

However, in this example, the first and second retaining members are supported by respective first and second lateral extensions 13A, 13B. The lateral extensions 13A, 13B extend perpendicularly from the stiff member 11 in its widthwise direction. The lateral extensions enable the stiff member 11 to be positioned at or near an edge of the housing 40 while the first and second retaining members 12A, 12B are positioned further into an interior volume of the housing 40.

At or near the mid-point of the stiff member 11, the stiff member 11 has an interior lateral tab 15 that extends perpendicularly from the stiff member 11 in its widthwise direction into the interior volume of the housing 40.

The object 30 abuts against the interior lateral tab 15 when inserted inwardly into the interior volume of the housing. The inwardly directed force that flips the configuration of the stiff member 11 from the first configuration 10 to the second configuration 10′ is consequently transferred from the object 30 through the interior lateral tab 15 to the stiff member 11.

At or near the mid-point of the stiff member 11, the stiff member 11 has an exterior lateral tab 14 that extends perpendicularly from the stiff member 11 in its widthwise direction away from the interior volume of the housing 40.

The object 30 does not abut against the exterior lateral tab 14 when inserted into the interior volume of the housing. However, the exterior lateral tab 14 extends beyond the edges of the housing 40.

The outwardly directed force that flips the configuration of the stiff member 11 from the second configuration 10′ to the first configuration 10 may be applied through the exterior lateral tab 14 to the stiff member 11.

In this example the stiff member 11; the first and second retaining members 12A, 12B; the lateral extensions 13A, 13B; the interior lateral tab 15; and the exterior lateral tab 14 are formed from the same one-piece of pressed metal sheet and has a thickness of, for example, between 0.1 and 1.8 mm or even between 0.1 and 0.5 mm. Consequently, the first and second retaining members 12A, 12B; the lateral extensions 13A, 13B; the interior lateral tab 15; and the exterior lateral tab 14 are all stiff.

However, the stiff member 11 and other features 12-15 may be made out of another material or out of different materials and attached together.

A suitable material for forming the stiff member 11 may be a material that has a high enough tensile strength not to brake in the first or second configuration. The material may be sufficiently elastic (resiliently deformable) to enable a transition from the first configuration to the second configuration by application of a force via an inserted object 30 that does not damage the object 30. The material may be sufficiently stiff to prevent a transition between the first configuration and the second configuration without application of a force above a threshold value. The stiff member 11 may be a thin, narrow elongate component that is formed from a material with sufficiently high Young's modulus, shear modulus and bulk modulus.

The stiff member 11 may be formed as a laminate. The laminate may, for example, be depth-wise or widthwise combination of distinct parts.

FIG. 12 illustrates an example of an alternative stiff member 11. In this example, the stiff member 11 is formed from two wires 61, 62 that are joined together such that they are side-by-side across the width W of the stiff member 11.

Therefore in this example the stiff member 11; the first and second retaining members 12A, 12B; the lateral extensions 13A, 13B; the interior lateral tab 15; and the exterior lateral tab 14 are formed from a pair of joined wires. The two shaped wires 61, 62 are laser spot welded at points 63A, 63B near the extremities of the stiff member 11. The wires run adjacent one another to form the stiff member 11; the first and second retaining members 12A, 12B and the lateral extensions 13A, 13B and separate to form respectively the interior lateral tab 15 and the exterior lateral tab 14. The interior lateral tab 15 is formed by a widthwise excursion and return of one of the wires 61 and the exterior lateral tab 14 is formed by the widthwise excursion (in an opposite direction) and return of the other wire 62.

The width W of the stiff member 11 in this example may be less than the width of the stiff member 11 in the example of FIG. 6A.

In the first configuration 10, the stiff member 11 has an outward curvature such that an upper (outward) surface of the stiff member 11 is in tension and a lower (inward) surface is in compression. The stiff member 11, in this configuration provides resistance to an inwardly directed force but not to an outwardly directed force.

In the second configuration 10′, the stiff member 11 has an inward curvature such that an upper (outward) surface of the stiff member 11 is in compression and a lower (inward) surface is in tension. The stiff member 11, in this configuration provides resistance to an outwardly directed force but not to an inwardly directed force.

FIGS. 7A and 7A illustrate the addition of electro-magnetic shielding 50 to the housing 40 to form a new housing. FIG. 7A is a top perspective view during addition of the shielding. FIG. 7B is a top perspective view after addition of the shielding.

The shielding 50 comprises sidewalls 51 that surround or circumscribe the sides of the housing. Fasteners 52 are provided for attaching the shielding 50 to the housing 40. In this example, the fasteners 52 are hooks that hook over the sidewalls and braces of the housing 40.

The shielding 50 has a slot like aperture 53 that is aligned with the exterior lateral tab 14. This enables exterior access to the exterior lateral tab 14. The exterior lateral tab 14 can move within the aperture 53 when the stiff member 11 moves and the length of the aperture 53 may, in some embodiments, be used to control the outward movement of the stiff member 11.

The shielded housing 40 may be soldered to a printed wiring board 58 of an electronic device to form an on-board socket. Electrical contacts on the printed wiring board 58 may be connected to the leaf spring contacts 45. The printed wiring board may provide the supporting surface 25. An object 30 may be inserted into the on-board socket at a subsequent stage of manufacture of the electronic device.

FIG. 8 is a top perspective view during insertion of an object 30 for retention into the housing 40. FIGS. 9A, 9B, 9C are side views of the housing 30 during insertion of an object 30 for retention into the housing 40. FIG. 10 is a side view after insertion of an object 30 into the housing 40.

FIGS. 9A, 9B and 9C illustrate the rotational movement of the first retaining member 12A as the stiff member 11 is moved inwards.

In FIG. 9A, the stiff member 11 has the first configuration 10 in which the stiff member 11 has an outward curvature and the first retaining member 12A is in a non-retaining configuration.

In FIG. 9B, the stiff member 11 is moving between the first configuration 10 and the second configuration 10′. The first retaining member 12A is moving from a non-retaining configuration to a retaining configuration.

In FIG. 9C and FIG. 10, the stiff member 11 has the second configuration 10′ in which the stiff member 11 has an inward curvature and the first retaining member 12A is in a retaining configuration and contacts a portion 31A of the object 30.

FIG. 11A is a top perspective view illustrating a release of a retained object 30 from the housing 40 using the exposed exterior lateral tab 14 to apply an outward force. FIG. 11B is a plan view illustrating a release of a retained object from the housing the exposed exterior lateral tab 14.

As used here ‘module’ refers to a unit or apparatus that excludes certain parts/components that would be added by an end manufacturer or a user. The object 30 may be a module. The housing 40, without the inserted object 30, may be a module.

Although embodiments of the present invention have been described in the preceding paragraphs with reference to various examples, it should be appreciated that modifications to the examples given can be made without departing from the scope of the invention as claimed.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/We claim:

1. An apparatus comprising:
a first support and a second support separated by a distance;
a stiff member configured to extend lengthwise between the first support and the second support and having a length greater than the distance; and
one or more retaining members coupled to the stiff member wherein the stiff member has a first configuration in which the stiff member has an outward curvature and the one or more retaining member are in a non-retaining configuration and
wherein the stiff member has a second configuration in which the stiff member has an inward curvature and the one or more retaining members are in a retaining configuration.

2. An apparatus as claimed in claim 1, wherein the one or more retaining members applies a continuous inward retaining force against a retained object when in the retaining configuration.

3. An apparatus as claimed in claim 2, wherein the retained object is sized and configured for retention by the one or more retaining members.

4. (canceled)

5. An apparatus as claimed in claim 2, wherein the retained object is a camera module for a hand-portable device.

6. An apparatus as claimed in claim 1, wherein the apparatus is bi-stable, having a first stable equilibrium configuration in which the stiff member is in the first configuration and a second stable equilibrium configuration in which the stiff member is in the second configuration.

7. An apparatus as claimed in claim 1, wherein in response to an inwardly directed force of increasing magnitude, the stiff member, while in the first configuration, initially provides resistance against the inwardly directed force and then switches configuration from the first configuration to the second configuration.

8. An apparatus as claimed in claim 7, wherein the stiff member comprises a first laterally extending tab against which a component abuts when inserted to apply the inwardly directed force.

9. An apparatus as claimed in claim 1, wherein in response to an outwardly directed force of increasing magnitude, the stiff member, while in the second configuration, initially provides resistance against the outwardly directed force and then switches configuration from the second configuration to the first configuration.

10. An apparatus as claimed in claim 9, wherein the stiff member comprises a second laterally extending tab against which an inserted component does not abut and via which the outwardly directed force can be applied

11. (canceled)

12. An apparatus as claimed in claim 1, comprising a first stiff retaining member attached to the stiff member at a first position that is closer to the first support that the second support and comprising a second stiff retaining member attached to the stiff member at a second position that is closer to the second support that the first support, wherein, the first stiff retaining member comprises a first contact portion for contacting an object retained by the retaining member, the second stiff retaining member comprises a second contact portion for contacting the object retained by the retaining member, and the first contact portion and the second contact portion are moved inwardly and towards each other when the stiff member changes from the first configuration to the second configuration.

13. (canceled)

14. (canceled)

15. An apparatus as claimed in claim 1, comprising a site area between the first support and the second support, wherein the stiff member has a first portion supported by the first support, a second portion supported by the second support and an intermediate portion, between the first and second portion, wherein in the first configuration the intermediate portion is further from the site area than the first and second portions and in the second configuration the intermediate portion is closer to the site area than the first and second portions and wherein the stiff member in the second configuration contacts the site area.

16. (canceled)

17. An apparatus as claimed in claim 15, wherein the site area comprises one or more electrical contacts for contacting an inserted object.

18. (canceled)

19. (canceled)

20. (canceled)

21. An apparatus as claimed in claim 1, further comprising a housing having first and second opposing sidewalls, wherein a first notch in the first sidewall provides the first support and wherein a second notch in the second sidewall provides the second support.

22. An apparatus as claimed in claim 21, wherein the first notch extends to an extremity of the first side wall and the second notch extends to a corresponding extremity of the second side wall such that the stiff member may be laterally inserted and supported between the first notch and the second notch.

23. (canceled)

24. An apparatus as claimed in claim 1, comprising a retainer for constraining outward movement of the stiff member when in the second configuration.

25. An apparatus as claimed in claim 24, wherein the retainer comprises an external cover for a hand portable electronic device.

26. An apparatus as claimed in claim 1, configured as a module for integration into a hand-portable device

27. An apparatus as claimed in claim 1, configured a hand-portable device.

28. A method comprising:
inwardly inserting a component against an outwardly curved stiff member that spans a distance less than its length;
continuing to inwardly insert the component against the outwardly curved stiff member until the stiff member buckles to become inwardly curved causing one or more retaining members coupled to the stiff member to retain the component.

29. A method as claimed in claim 28, comprising: attaching a housing comprising the stiff member to a printed wiring board before the insertion of the component.

30. A method as claimed in claim 28, placing a cover for a mobile electronic device over the inserted component to constrain outward movement of the inwardly curved stiff member.

31. (canceled)

32. (canceled)

33. A method comprising:
applying an outward force against an inwardly curved stiff member that spans a distance less than its length and that uses one or more retaining members to retain a component; and
continuing to apply an outward force until the stiff member buckles to become outwardly curved causing the one or more retaining members to release the component.

34. A method as claimed in claim 33, comprising, before applying the outward force, removing a cover for a mobile electronic device over the inserted component to enable outward movement of the inwardly curved stiff member.

35. A method as claimed in claim 33, comprising applying the outward force via a second laterally extending tab of the stiff member.

36. A method as claimed in claim 33, further comprising:
removing the released component;
inwardly inserting a replacement component against the outwardly curved stiff member; and
continuing to inwardly insert the replacement component against the outwardly curved stiff member until the stiff member buckles to become inwardly curved causing one or more retaining members coupled to the stiff member to retain the replacement component.

37. (canceled)
